(19) United States
(12) Patent Application Publication
(10) Pub. No.: US 2007/0080285 A1
(43) Pub. Date: Apr. 12, 2007

(54) Arrangement for increasing the fill factor in a four-quadrant-type detector

(75) Inventor: Dov Lavi, Haifa (IL)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: RAFAEL-ARMAMENT DEVELOPMENT AUTHORITY LTD.

(21) Appl. No.: 11/517,928

(22) Filed: Sep. 8, 2006

(30) Foreign Application Priority Data
Sep. 8, 2005 (IL) 170765

(51) Int. Cl. H01L 31/00

(52) U.S. Cl. 250/214.1

(57) ABSTRACT

The invention relates to a four-quadrant detector based optical system for detecting and tracking an optical spot, which comprises: (a) a four quadrant detector, which comprises four surfaces that are sensitive to light, said surfaces being separated one from the others by a dead zone surface which is non-sensitive to light radiation; (b) optics between said detector and the scenery, for acquiring an image of a light spot at the scenery, and for impinging the image of the same on said surfaces of the decoder; and (c) a refraction element between said detector and the other optics, which comprises grooves for diverting only the light rays coming from the scenery and directed toward the dead zone, each to a corresponding proximate sensitive to light surfaces of the decoder, while not disturbing the other coming light rays, wherein said refraction element has no physical contact with any of said detector surfaces.

### FIELD OF THE INVENTION

The present invention relates to the field of optical detectors. More particularly, the invention relates to an arrangement for increasing the fill factor in a four quadrant photo detector.

### BACKGROUND OF THE INVENTION

A four quadrant optical detector is typically used for the optical tracking of objects that are lighted by a light spot (such as a spot in the laser band). A four quadrant detector is made of four separate substrates that are sensitive to light, and which are separated by narrow, non-sensitive to light gaps which form a cross like “dead zone”. Although the dead zone is relatively narrow, the fact that a portion of the light image impinges on the non-sensitive dead zone causes reduction in the effectiveness of the detector. The rate of the light impinging on the sensitive areas of the four quadrant detector relative to the total light impinging on the detector surface (including the dead zones) is commonly referred to in the art as “fill factor”. In some cases, the dead zone may cause reduction of the fill factor by 30% (this value depends on the detector surface size on the dimensions of the dead zone, and on the size of the light spot image), reduction that when the tracked light spot is of low intensity may cause the tracking to be non-effective, or even to a total loss of the tracked spot.

U.S. Pat. No. 5,204,520 discloses a structure for a four quadrant substrate detector, which has wedge-shaped reflectors at the dead zone, back reflectors at the periphery of the detector, and anti-reflection coating in front of the sensitive portions of the detector. Each light ray that is directed toward the dead zone is diverted by a wedge reflector toward a corresponding back reflector, and then from the back reflector the light ray is reflected again toward the corresponding closest sensitive quadrant. This patent uses reflector coatings of chrome or gold which are expensive. Also, the structure is complicated, has to be produced during the production process of the detector, and obviously requires more processing steps than a conventional four-quadrant detector. Furthermore, as the structure of this patent is integrated within the detector, it cannot be applied to an existing, conventional four quadrant detector.

It is an object of the present invention to provide arrangement for diverting illumination rays from non-sensitive regions (dead zone) of a four quadrant detector toward the corresponding closest sensitive quadrant, with a minimum loss of light energy.

It is another object of the present invention to provide an arrangement that does not require utilization of expensive and complicated processes for production, such as the coating and etching process for producing the reflection diverting coating of the prior art.

It is still an object of the present invention to provide an arrangement which is external and independent of the detector, for diverting illumination directed to the dead zone toward corresponding proximate sensitive quadrants.

It is still an object of the present invention to provide a structure which is not integral with the detector, and which can easily be applied to a conventional four-quadrant detector of the prior art.

It is still another object of the invention to obtain all said features by applying widely used conventional technology.

Other objects and advantages of the present invention will become apparent as the description proceeds.

### SUMMARY OF THE INVENTION

The invention relates to a four-quadrant detector based optical system for detecting and tracking an optical spot, which comprises: (a) a four quadrant detector, which comprises four surfaces that are sensitive to light, said surfaces being separated one from the others by a dead zone surface which is non-sensitive to light radiation; (b) optics between said detector and the scenery, for acquiring an image of a light spot at the scenery, and for impinging the image of the same on said surfaces of the decoder; and (c) a refraction element between said detector and the other optics, which comprises grooves for diverting only the light rays coming from the scenery and directed toward the dead zone, each to a corresponding proximate sensitive to light surfaces of the decoder, while not disturbing the other coming light rays, wherein said refraction element has no physical contact with any of said detector surfaces.

Preferably, said dead zone separating the four quadrant surfaces has an essentially cross-like profile, wherein the grooves at said refraction element also form a cross-like profile similar to the profile of said dead zone.

Preferably, the grooves of the refraction element have a v-shaped cross-section formed by two slanted surfaces that are joined at the center of the groove.

Preferably, the surfaces of the refraction element at locations other than those of the grooves are designed not to affect the direction of the light rays passing through them.

Preferably, the detector is mounted within a detector casing, wherein the refraction element is embedded with a front window at the detector casing.

Preferably, the refraction element is made of glass.

Preferably, the grooves are juxtaposed with respect to the dead zone.

Preferably, the refraction element is coated by an anti-reflection coating.

### BRIEF DESCRIPTION OF THE DRAWINGS

In the drawings:

FIG. 1 shows a prior art four quadrant detector, with an image of a light spot shown falling at the center of the detector;

FIG. 2 shows the detector of FIG. 1, with an image of a light spot falling on one quadrant surface of the detector which is sensitive to light;

FIG. 3 shows the structure of refraction element of the invention;

FIGS. 4 and 5 schematically show a side view of the refraction element and of the detector. The dimensions appearing in FIG. 5 are those used in the simulations of FIGS. 6, 7, and 8;

FIG. 6 shows a simulation in which an image of a light spot falls at the center of the detector, according to the prior art;

FIG. 7 shows a simulation as in FIG. 6, but in which the refraction element according to the invention is used in front of the detector;

FIG. 8 shows a simulation with the refraction element of the present invention in which the image of the light spot fully falls along a horizontal section of the dead zone; and

FIG. 9a shows a cross-sectional view of a detector casing according to the prior art. FIG. 9b shows a cross-sectional view of a detector casing in which the front window is modified to include the refraction element of the present invention.

### DETAILED DESCRIPTION OF PREFERRED EMBODIMENTS

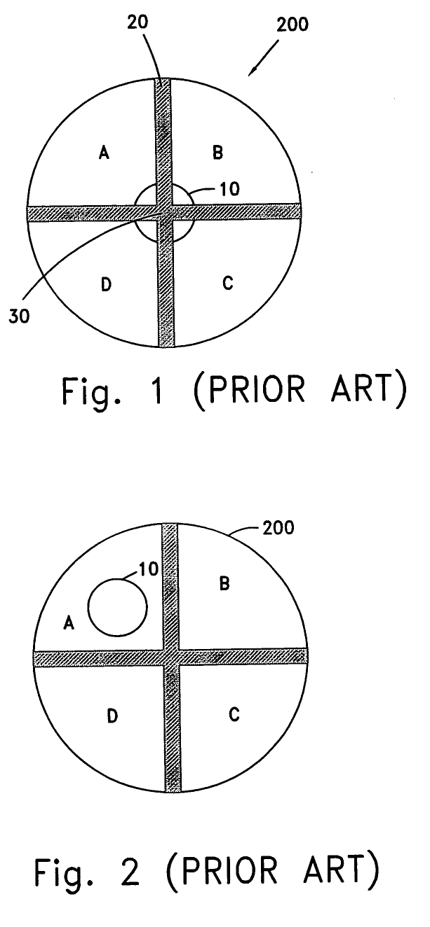

FIG. 1 illustrates a conventional prior art four quadrant detector 200 of an optical tracking device, which may be, for example, installed in a flying vehicle. Each of the quadrants A, B, C, and D is a surface which is sensitive to light. The four-quadrant surfaces are separated by a cross-like dead zone 20. In a typical case, the detector looks toward a light spot (such as a laser spot) the image of which as impinged on the detector is indicated by numeral 10. The object of the steering system of the flying vehicle (not shown) is to adjust the vehicle direction such that the center of the image 10 of the light spot coincides with center 30 of the detector. If however, the image center does not coincide with the detector 200 center (for example as shown in FIG. 2), the steering system is activated to adjust the vehicle direction such that the spot is centralized as in FIG. 1.

As said, the dead zone 20 which separates between the four quadrants is not sensitive to light. Therefore, according to the prior art, the energy of the photons which impinge on the dead zone is lost. It should be noted that the highest loss of energy occurs during the best tracking case of FIG. 1, as the area of the dead zone 20 spans a largest portion of the image 10 of the spot. It should also be noted that a loss of the spot light energy causes reduction of the tracking capability, and in severe cases when the intensity of the spot is low, the energy reduction may cause the tracking to fail.

The present invention provides an arrangement which enables the recovery of the energy in the prior art is due to impinging the dead zone 20.

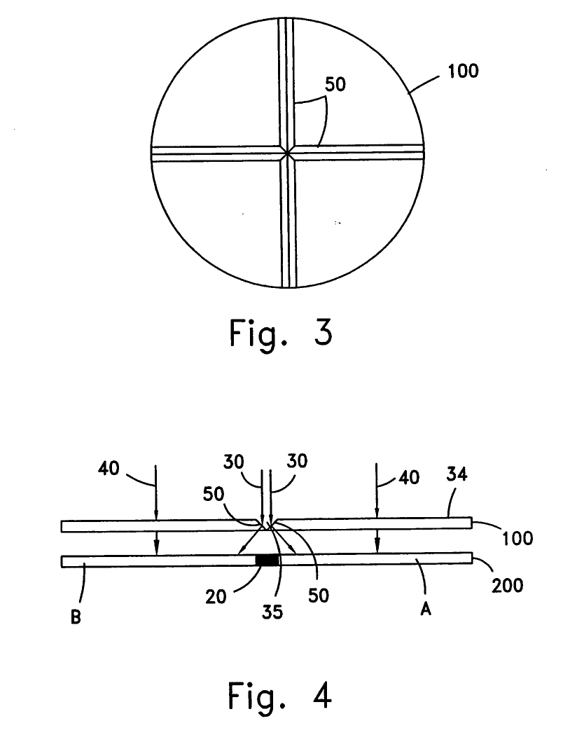

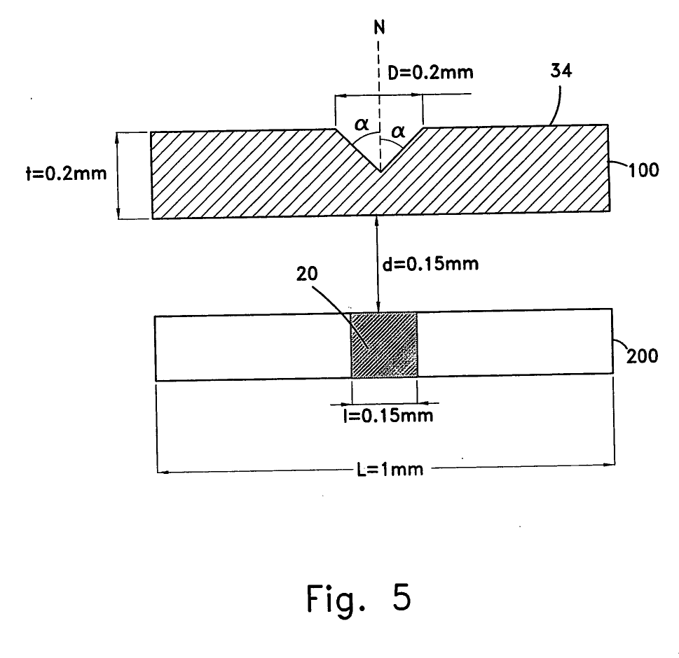

According to the present invention, and with reference to FIGS. 3 and 4, a refraction element 100 is provided in front of the detector 200. The refraction element is located some distance from detector 200, and separated thereof. Refraction element 100 has a v-shaped or similar groove 35 which is juxtaposed with respect to the dead zone 20 of detector 200. The faces 50 of the v-shaped groove 35 are designed to refract all the light which is directed toward the dead zone, and to direct such light toward a corresponding closest quadrant of the detector. The faces of the v-shaped groove are sloped with respect to the other front surface 34 of the refraction element, forming each an angle α with respect to the normal N, as shown in FIG. 5. It should be noted that it is important to divert the light from dead zone to the proximate surface in order to maintain the accuracy of the detector.

As shown in FIG. 4, light rays 40 that are directed toward the light sensitive surfaces A, B, C, or D, pass undisturbed through the refraction element 100, and impinge on the corresponding sensitive quadrant of the detector. Light rays 30 that are directed toward the dead zone 20 of detector 200 are refracted by surfaces 50, and diverted toward the corresponding proximate light sensitive surface. Of course, the specific design of the refraction element groove is governed by Snell's Law, as follows:
n₁ sin θ₁=n₂ sin θ₂
Wherein n₁ is the coefficient of refraction of the first media (generally the air), and n₂ is the coefficient of refraction of the second media (the material of the prism). θ₁ and θ2 (not shown) are the entrance and exit angles of the light ray with respect to the normal of the face 50. The design should of course take into account other dimension factors, such as the distance d between the refraction element 100 and the light sensitive surfaces of detector 200, the width l of the dead zone, the thickness t of the refraction element 100, and in some cases also the total length of the detector. As said, all such parameters should ensure the light rays which impinge on surfaces 50 are refracted, and diverted to the proximate sensitive zone.

FIG. 5 provides an example for some dimensions of the refraction element 100, the detector 200, and the distance between them. The detector 200 diameter L is 1 mm, wherein dead zone width l is 0.15 mm. The thickness t of prism 100 is 0.2 mm, and the refraction element is located a distance d of 0.15 mm from the sensitive surface of detector 200. The width of the refraction element groove is 0.2 mm, and the slope a of the v-shaped groove is 45° with respect to the normal N. The refraction element 100 of the invention is preferably made of glass.

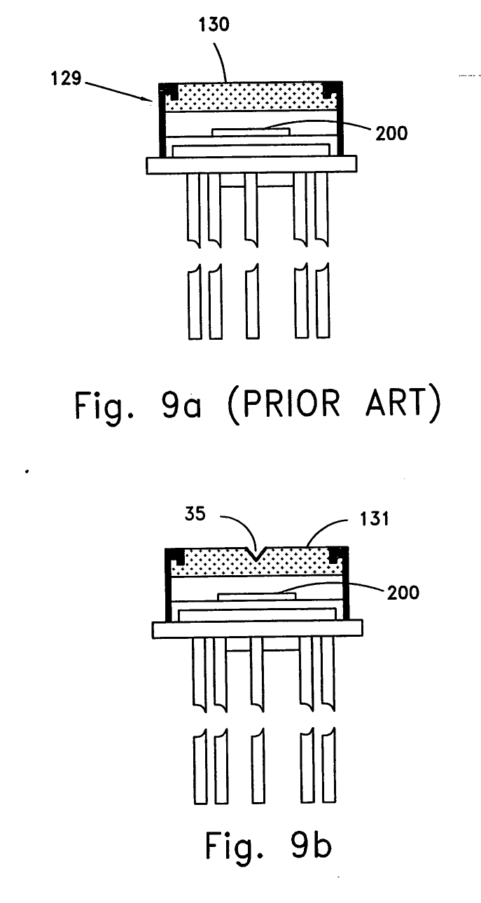

Some of the prior art four quadrant detectors are provided within a casing. Such a prior art casing is illustrated in FIG. 9a. The detector 200 is located within casing 129, wherein the upper surface of the casing has a transparent window 130, through which the radiation coming from the scenery and through the optics enters and impinges the detector's 200 front surface. As said, the prior art system suffers from some losses due to the dead zone of the four quadrant detector. In an embodiment of the invention shown in FIG. 9b, the said front window 130 is modified to include the v-shaped grooves of the invention. Such a modified window is indicated by numeral 131 in FIG. 9b. The advantage of the embodiment of FIG. 9b is that the refraction element is embedded within the front window of the detector casing 129. However, this is not a necessity, as the window may be totally separated from the detector casing, and located within the optics in front of the detector casing.

It should be noted that in order to obtain the highest increase of the fill factor, the refraction element should be juxtaposed with respect to the detector, such that the grooves of the refraction element overlap the dead zone. In general, it is advisable to provide alignment means at the apparatus in order to obtain such accurate alignment, or to rigidly mount the refraction element at a fixed position as in the embodiment of FIG. 9b. Furthermore, the refraction element is preferably coated in all the embodiments by an anti-reflection coating, in order to obtain highest efficiency.

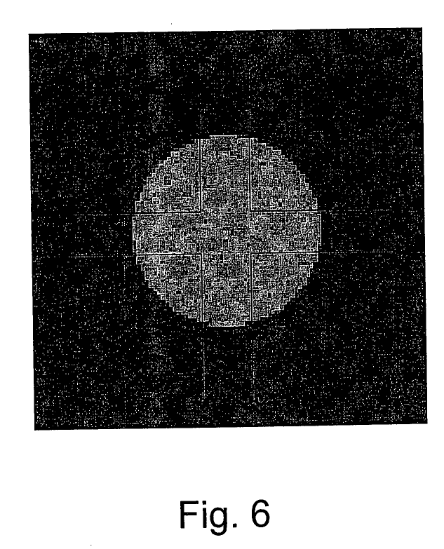

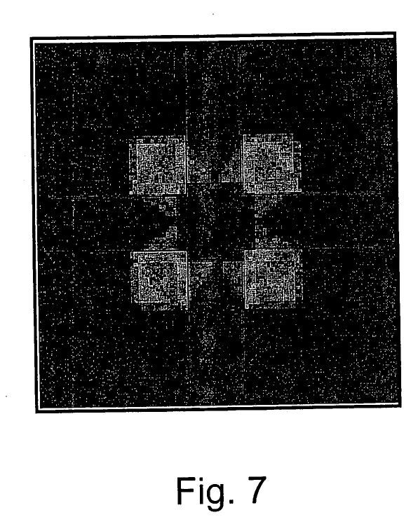

A simulation was made with the structure of FIG. 5, with a light spot image having a diameter of 450 μm. A first simulation was made for a light image spot positioned exactly at the center of the detector as shown in FIG. 6. In that case, the energy loss due to the dead zone was 66% of the total light energy. The addition of a refraction element 100 according to the invention has caused diversion of the light rays from the dead zone 20 toward corresponding sensitive zones A, B, C, and D, respectively. The addition of the refraction element has caused reduction in the energy loss to 12% of the total energy. The simulation result with the refraction element added, as appeared on the detector is shown in FIG. 7. As can be seen, the light rays which were originally directed to the dead zone have been refracted, and therefore diverted each to the proximate sensitive quadrant of the detector.

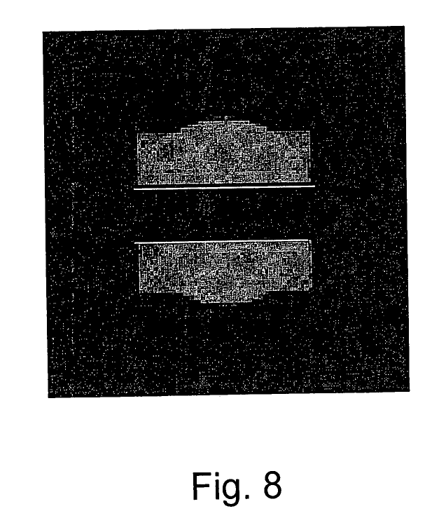

A second simulation was made with said light spot image, however, in this case falling along a horizontal section of the dead zone. The energy loss due to the dead zone before using the refraction element 100 of the invention was found to be 42% of the total light energy. The addition of the refraction element of the invention has reduced the light energy loss to essentially 0% of the total energy. The result of the said second simulation is shown in FIG. 8. A same result was obtained with a light spot falling along a vertical section of the dead zone.

As shown, the present invention provides a significant reduction of the energy loss due to the dead zone in a four quadrant detector. The refraction element of the present invention is positioned in front of the detector, and separated thereof, and is essentially a part of the optics. As shown the structure of the refraction element of the present invention is simple, and therefore can be made by conventional machinery.

While some embodiments of the invention have been described by way of illustration, it will be apparent that the invention can be carried into practice with many modifications, variations and adaptations, and with the use of numerous equivalents or alternative solutions that are within the scope of persons skilled in the art, without departing from the spirit of the invention or exceeding the scope of the claims.

1. An optical system for detecting and tracking an optical spot, comprising:
a. a four quadrant detector, which in turn comprises four surfaces that are sensitive to light; said surfaces being separated one from the others by a dead zone surface which is non-sensitive to light radiation;
b. optics between said detector and the scenery, for acquiring an image of a light spot at the scenery, and for impinging the image of the same on said surfaces of the decoder; and
c. a refraction element between said detector and the other optics, which comprises grooves for diverting only the light rays coming from the scenery and directed toward the dead zone, each to a corresponding proximate sensitive to light surface of the decoder, while not diverting the other coming light rays directed to sensitive to light surfaces of the decoder, wherein said refraction element has no physical contact with any of said detector surfaces.

2. System according to claim 1, wherein said dead zone separating the four quadrant surfaces has an essentially cross-like profile, and wherein the grooves at said refraction element also form a cross-like profile similar to the profile of said dead zone.

3. System according to claim 1, wherein each groove of the refraction element has a v-shaped cross-section formed by two slanted surfaces that are joined at the center of the groove.

4. System according to claim 1, wherein surfaces of the refraction element at locations other than those of the grooves are designed not to affect the direction of the light rays passing through them.

5. System according to claim 1, wherein the refraction element is made of glass.

6. System according to claim 1, wherein the detector is mounted within a detector casing, and wherein the refraction element is embedded with a front window at the detector casing.

7. System according to claim 1, wherein the grooves are juxtaposed with respect to the dead zone.

8. System according to claim 1, wherein the refraction element is coated by an anti-reflection coating.
